(19) United States
(12) Patent Application Publication
(10) Pub. No.: US 2008/0197402 A1
(43) Pub. Date: Aug. 21, 2008

(54) Methods of Forming Nonvolatile Memory Devices and Memory Devices Formed Thereby

(75) Inventors: Seung-woo Paek, Seoul (KR); Dae-hyun Jang, Gyeonggi-do (KR); Jin-hong Kim, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/031,896

(22) Filed: Feb. 15, 2008

(30) Foreign Application Priority Data
Feb. 16, 2007 (KR) 2007-16448
Sep. 27, 2007 (KR) 2007-97395

(51) Int. Cl. H01L 29/788; H01L 21/336

(52) U.S. Cl. 257/316; 438/266; 257/E29.3

(57) ABSTRACT

Methods of forming non-volatile memory devices include forming a device isolation layer and a gate pattern of a non-volatile memory cell transistor, on a semiconductor substrate. This gate pattern includes a floating gate electrode and a control gate line that extends on the floating gate electrode and on the device isolation layer. At least a first portion of a first sidewall of the gate pattern is then covered with a first mask that exposes upper corners of the control gate line. The device isolation layer is then selectively etched at a first rate to define an at least partial opening therein. During this etching step, the upper corners of the control gate line are also etched back at a second rate less than the first rate.

### CROSS-REFERENCE TO RELATED APPLICATIONS

This application is related to U.S. application Ser. No. 11/103,069, filed Apr. 11, 2005, now U.S. Pat. No. ______, the disclosure of which is hereby incorporated herein by reference.

### REFERENCE TO PRIORITY APPLICATIONS

This application claims priority to Korean Patent Application Nos. 2007-16448, filed Feb. 16, 2007 and 2007-97395, filed Sep. 27, 2007, respectively, the disclosures of which are hereby incorporated herein by reference.

### FIELD OF THE INVENTION

The present invention relates to methods of forming integrated circuit devices and, more particularly, to methods of forming integrated circuit memory devices and devices formed thereby.

### BACKGROUND OF THE INVENTION

In order to enhance the integration density of flash memory devices, the number of contact patterns formed to each cell transistor can be reduced. In this manner, the integration density of the flash memory device can be enhanced by reducing the space occupied by the contact patterns and/or separation space between the gate patterns. A nonvolatile memory device can contain a unit cell having a simple structure relative to a DRAM device or a SRAM device, which enables increased integration density relative to the DRAM device or the SRAM device. For example, a cell transistor in a flash memory device can have a structure similar to a MOS transistor.

FIG. 1 represents a cross sectional view of a conventional flash memory device. Referring to FIG. 1, active regions are defined by device isolation layers (not shown) and a plurality of gate patterns (19) cross the active regions in parallel. The gate pattern (19) may contain a tunnel insulating layer (12), a floating gate (14), an intergate dielectric layer (16) and a control gate (18). A source region (20s) is positioned adjacent one side of an active region, and a drain region (20d) is positioned adjacent the opposite side of the active region. A sidewall spacer (22) may be positioned on both sidewalls of the gate pattern (19). A bitline contact is connected to the drain region (20d) through an interlevel dielectric layer (24). A plurality of drain regions (20d) arranged in the same direction as the gate pattern (19) may be separated with respect to each other by the device isolation layer. The source region (20s) may have a line shape, which extends in the direction that the gate pattern (19) extends. When the source region (20s) is formed with a line shape, the device isolation layer positioned adjacent to the one side of the gate pattern (19) may be removed.

In order to selectively remove the device isolation layer between active regions adjacent to one side of the gate pattern (19), a self-aligned source formation process may be performed. The self-aligned source formation process may include a self-aligned source mask patterned to cover the drain regions (20d) positioned adjacent to the opposite side of the gate pattern (19), with the device isolation layer therebetween. In other words, using the self-aligned mask pattern, the device isolation layer positioned adjacent to the one side of the gate pattern (19) may be removed.

In order to secure sufficient alignment margin between the self-aligned mask pattern and the semiconductor substrate (10), the self-aligned mask pattern may cover a portion of the gate pattern (19) adjacent to the drain region (20d). However, another portion of the gate pattern adjacent to the source region (20s) may be exposed, and thereby, the gate pattern (19), especially the exposed portion of the control gate (18), may be etched.

Therefore, as illustrated, an upper portion (30) of the control gate (18) adjacent to the drain region (20d) may be formed higher than another upper portion (32) of the control gate (18) adjacent to the source region (20s). As a result, the sidewall of the control gate (18) adjacent to the drain region (20d) and the bitline contact (26) may be positioned closely together, and thereby, the control gate (18) and the bitline contact (26) may become electrically shorted.

### SUMMARY OF THE INVENTION

Methods of forming non-volatile memory devices according to embodiments of the present invention include forming a device isolation layer and a gate pattern of a non-volatile memory cell transistor, on a semiconductor substrate. This gate pattern includes a floating gate electrode and a control gate line that extends on the floating gate electrode and on the device isolation layer. At least a first portion of a first sidewall of the gate pattern is then covered with a first mask that exposes upper corners of the control gate line. The device isolation layer is then selectively etched at a first rate to define an at least partial opening therein. During this etching step, the upper corners of the control gate line are also etched back at a second rate less than the first rate. The first mask is used as an etching mask during these etching steps.

According to additional aspects of these embodiments of the present invention, source region dopants are implanted through the at least partial opening in the device isolation layer and into the semiconductor substrate to define a source region therein. Sidewall insulating spacers are also formed on opposing sidewalls of the gate pattern and then an interlayer dielectric layer is formed on the gate pattern. A step is performed to selectively etch through the interlayer dielectric layer and define a contact hole therein that exposes the semiconductor substrate. The contact hole is then filled with a bit line contact.

Alternatively, sidewall insulating spacers may be formed on opposing sidewalls of the gate pattern and then an electrically insulating barrier layer, formed of a first electrically insulating material, is formed on the sidewall insulating spacers. An interlayer dielectric layer, formed of a second electrically insulating material that is different from the first electrically insulating material, is then formed on the gate pattern. The interlayer dielectric layer and the electrically insulating barrier layer are then etched in sequence to define a contact hole therein that exposes the semiconductor substrate. The contact hole is filled with a bit line contact.

According to additional aspects of these embodiments of the invention, the step of covering at least a first portion of a first sidewall of the gate pattern includes depositing a mask layer on the gate pattern and then photolithographically patterning the mask layer to define a preliminary mask pattern that exposes a second sidewall of the gate pattern and exposes an upper surface of the device isolation layer. The preliminary mask pattern (e.g., photoresist pattern) is then etched back for a sufficient duration to define the first mask, which exposes an upper surface of the gate pattern and exposes a second portion of the first sidewall. According to aspects of these embodiments of the invention, etching back the preliminary mask pattern may include exposing the preliminary mask pattern to an oxygen plasma and/or a wet etchant, such as an etchant containing sulfuric acid.

### BRIEF DESCRIPTION OF THE DRAWINGS

FIG. 1 represents a cross sectional view of a conventional flash memory device.

FIG. 2a represents a plan view of a layout of a nonvolatile memory device in accordance with an embodiment of the present invention.

FIG. 2b represents a cross sectional view of the device of FIG. 2a taken along a line 2B-2B′.

FIG. 2c represents a cross sectional view of the device of FIG. 2a taken along a line 2C-2C′.

FIG. 2d represents an expanded cross sectional view of the gate pattern and bitline contact of FIG. 2b.

FIGS. 3a-7a are plan views of intermediate structures that illustrate methods of forming nonvolatile memory devices according to embodiments of the present invention.

FIGS. 3b-3c are cross-sectional views of the intermediate structure of FIG. 3a, taken along lines 3B-3B′ and 3C-3C′, respectively.

FIGS. 4b-4c are cross-sectional views of the intermediate structure of FIG. 4a, taken along lines 4B-4B′ and 4C-4C′, respectively.

FIGS. 5b-5c are cross-sectional views of the intermediate structure of FIG. 5a, taken along lines 5B-5B′ and 5C-5C′, respectively.

FIGS. 6b-6c are cross-sectional views of the intermediate structure of FIG. 6a, taken along lines 6B-6B′ and 6C-6C′, respectively.

FIGS. 7b-7c are cross-sectional views of the intermediate structure of FIG. 7a, taken along lines 7B-7B′ and 7C-7C′, respectively.

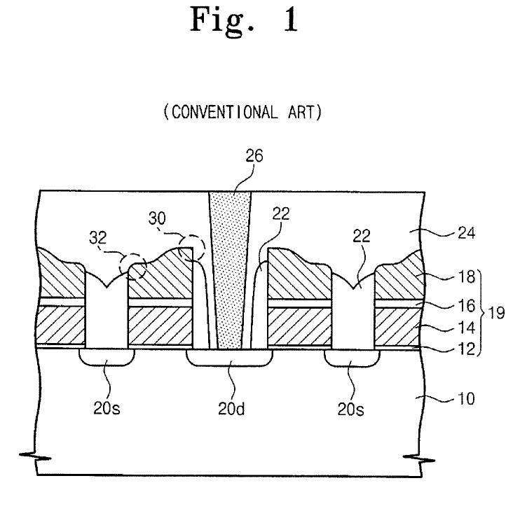

### DETAILED DESCRIPTION OF PREFERRED EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. It will be understood that when an element such as a layer, region or substrate is referred to as being “on” another element, it can be directly on the other element or intervening elements may also be present. In contrast, when an element is referred to as being “directly on” another element, there are no intervening elements present. Moreover, each embodiment described and illustrated herein includes its complementary conductivity type embodiment as well.

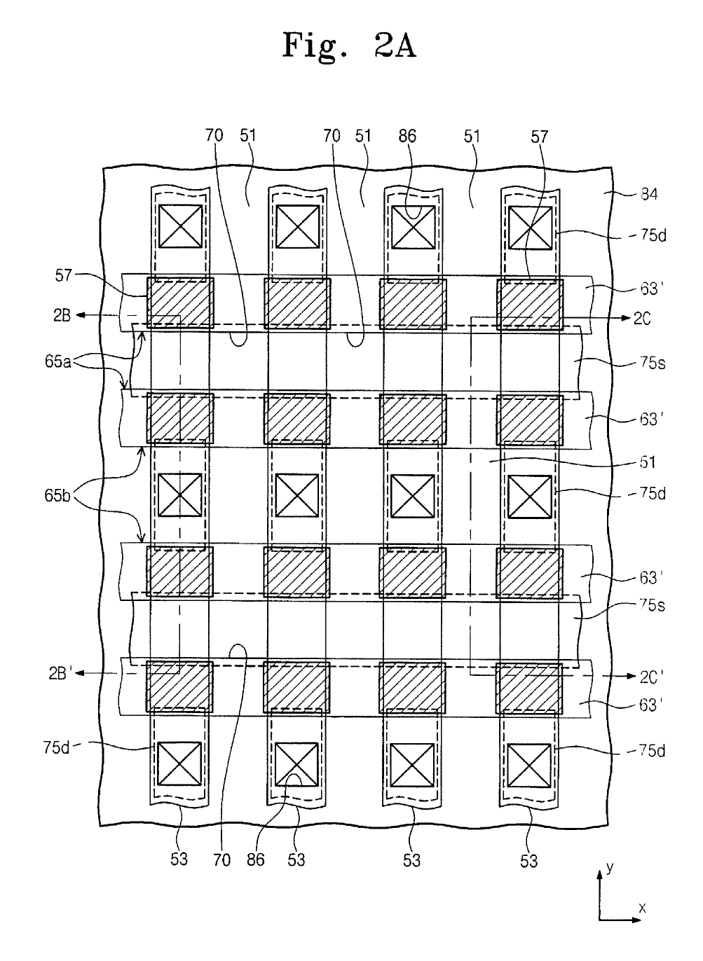

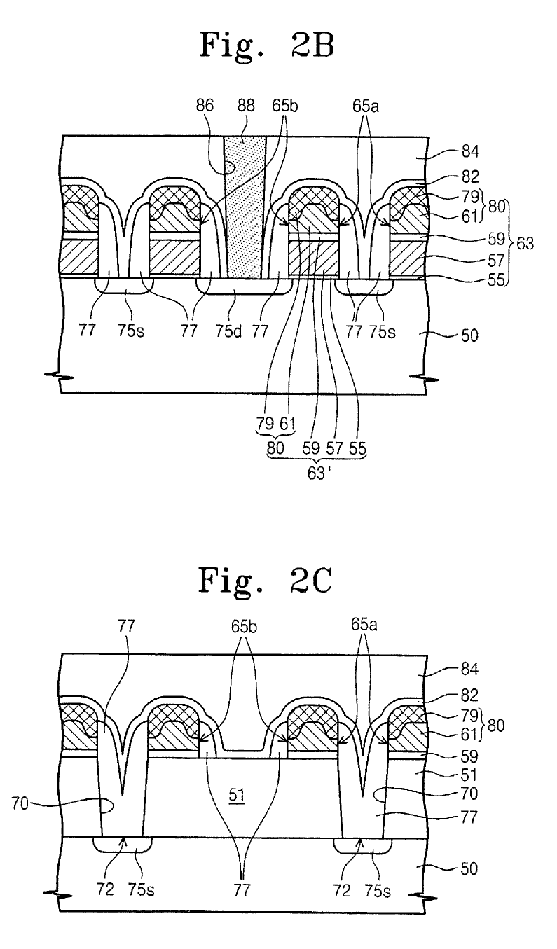

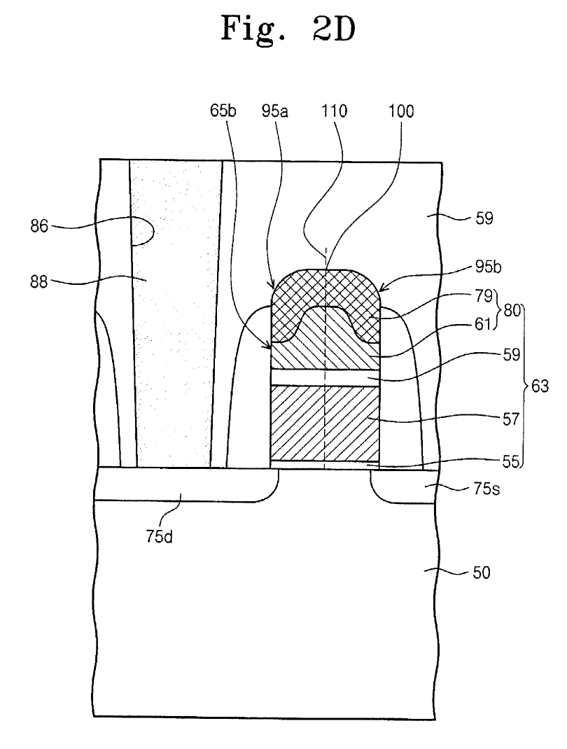

FIG. 2a represents a plan view of a layout of a nonvolatile memory device in accordance with an embodiment of the present invention, and FIG. 2b is a cross-sectional view taken along line 2B-2B′ of FIG. 2a, and FIG. 2c is a cross-sectional view taken along line 2C-2C′ of FIG. 2a, and FIG. 2d is an expanded view of the gate pattern and bitline contact of FIG. 2b. Referring to FIG. 2a, FIG. 2b, FIG. 2c and FIG. 2d, a device isolation layer (51) is arranged to define a plurality of active regions (53) on a semiconductor substrate (50). The active regions (53) may have a line shape and extend in parallel in a first direction across the underlying substrate. The device isolation layer (51) may be formed as a trench isolation layer. Namely, the device isolation layer (51) may be arranged in the trench defining the active regions (53). The active region (53) is a portion of the semiconductor substrate (50). FIG. 2b is a cross sectional view taken along the active region (53), and FIG. 2c is a cross section taken along the device isolation layer (51). Therefore, in FIG. 2b, the device isolation layer (51) is not shown.

A plurality of gate patterns (63′) cross the device isolation layer (51) and the active regions (53) in parallel. The gate patterns (63′) extend along a second direction perpendicular to the first direction. In the drawings, the y-direction corresponds to the first direction, and the x-direction corresponds to the second direction. Also, the second direction is the direction in which the gate pattern (63′) extends. The gate pattern includes a tunnel insulating layer (55), a charge storage layer (57), a blocking insulating layer (59) and a control gate (80). The control gate (80) crosses over the device isolation layer (51) and the active regions (53), and the charge storage layer (57) is interposed between the active region (53) and the control gate (80). The tunnel insulating layer (55) is interposed between the charge storage layer (57) and the active region (53), and the blocking insulating layer (59) is interposed between the charge storage layer (57) and the control gate (80).

The tunnel insulating layer (55) may be formed from an oxide layer. The charge storage layer (57) may be formed from a semiconductor material. Alternatively, the charge storage layer (57) may be formed from a material, such as nitrided silicon or a nanocrystal, which have deep level traps. The blocking insulating layer (59) may be formed as an ONO (Oxide-Nitride-Oxide) layer. Alternatively, the blocking insulating layer (59) may include a high dielectric material having a dielectric constant higher than that of the tunnel insulating layer (55). For example, the high dielectric material may be an insulating metal oxide such as hafnium oxide and aluminum oxide.

The control gate may include a sequentially stacked conductive line pattern (61) and silicide pattern (79). The conductive line pattern (61) may be formed from a semiconductor material including silicon. The silicide pattern (79) may be formed from various metal silicides, but cobalt silicide or nickel silicide is preferred.

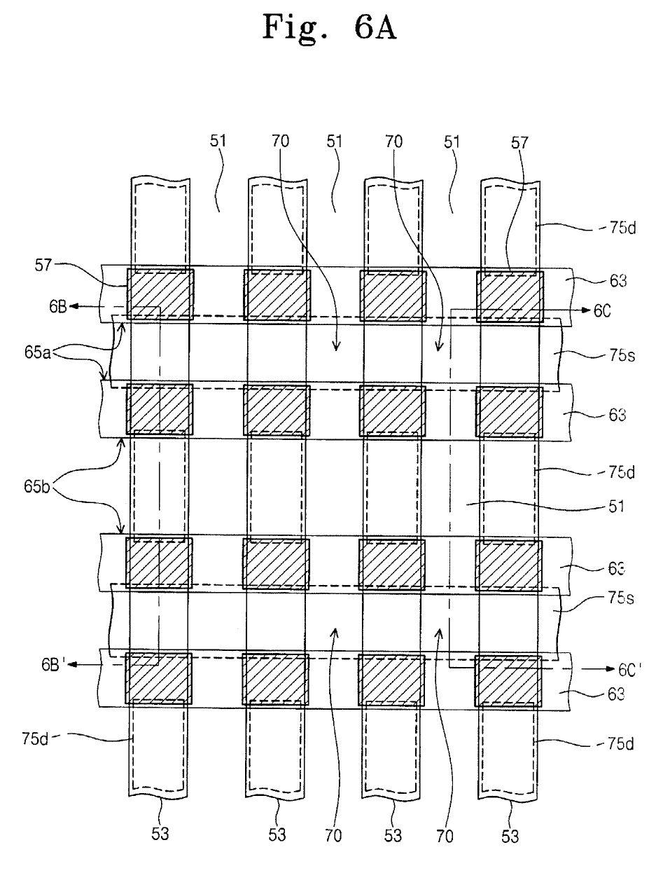

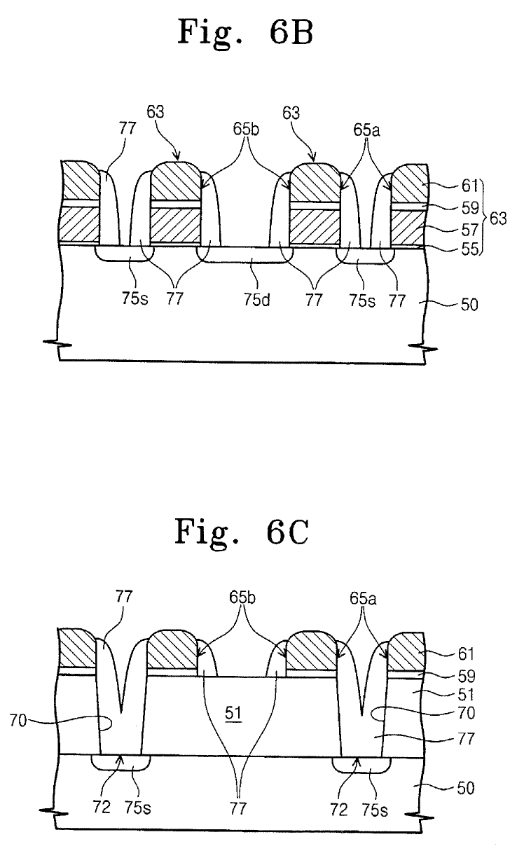

In accordance with an embodiment of the present invention, the conductive line pattern (61) may include a conductive material having a sufficiently low resistivity. At that case, the silicide pattern (79) may be omitted. Also, the conductive line pattern (61) may include at least one material selected from the group consisting of conductive metal nitride (for example, titanium nitride or tantalum nitride) and metal (for example, tungsten or molybdenum). When the silicide pattern (79) is omitted, the gate pattern (63′) may be replaced into the gate pattern (63) as shown in FIG. 6b. As illustrated, the upper edge of the gate pattern (63) adjacent to the drain region (75d) is formed to have a height lower than a center of the upper surface of the gate pattern (63). The upper surface of the gate pattern (63) in FIG. 6b is the upper surface of the conductive line pattern (61) in FIG. 6b. Details related to this are stated below.

The source region (75s) is arranged on the active region (53) adjacent to the one side of the gate pattern (63′), and the drain region (75d) is arranged on the active region (53) adjacent to the other side of the gate pattern (63′). The one sidewall of the gate pattern (63′) adjacent to the source region (73s) is defined as a first sidewall (65a), and the other sidewall of the gate pattern (63′) adjacent to the drain region (75d) is defined as a second sidewall (65b).

A pair of gate patterns (63′) arranged in both sides of the source region (75s) may be symmetric with each other with reference to the source region (75s). Accordingly, a pair of adjacent first sidewalls (65a) oppose each other with the source region (75s) therebetween. The pair of adjacent first sidewalls (65a) is included in gate patterns (63′) arranged on the both sides of the source region (75s), respectively. Likewise, gate patterns (63′) arranged on both sides of the drain region (75d) are symmetric with each other with reference to it. Accordingly, a pair of adjacent second sidewalls (65b) oppose each other with the drain region (75d) therebetween. The pair of adjacent second sidewalls (65b) is included in the gate patterns (63′) arranged on both sides of the drain region (75d), respectively.

A concave region (70), which represents a region where the device isolation layer (51) is etched away, is arranged on the one side of the gate pattern (63′). In other words, the concave regions are arranged between the pair of adjacent first sidewalls (65a). More specifically, the active regions (53) and the concave regions (70) are arranged alternately in the direction of the second direction (i.e., the direction in which the gate pattern (63′) extends) between the pair of adjacent first sidewalls (65a). A portion of the semiconductor substrate is arranged beneath the bottom surface (72) of the concave region (70). As illustrated, the bottom surface (72) of the concave region (70) may be a portion of the semiconductor substrate (50). Alternatively, the bottom surface (72) of the concave region (70) may be another material. For example, the bottom surface (72) of the concave region (70) may be a residue of the device isolation layer (51). Details as to this are stated below.

The source regions (75s) formed respectively on the active regions (53) between the pair of adjacent first sidewalls (65a) extends to be connected to the semiconductor substrate (50) beneath the bottom surface (72) of the concave region (70). Accordingly, a common source line extends along the semiconductor substrate (50) beneath the active regions (53) and the concave regions (70) between the pair of adjacent first sidewalls (65a). The common source line includes source regions extended between the pair of adjacent first sidewalls (65a). Preferably, the upper surface of the semiconductor substrate (50) beneath the concave region (70) is formed to be lower than that of the active region (51).

To the contrary, the active region (53) and the device isolation layer (51) between the pair of adjacent second sidewalls (65b) are arranged in the second direction. Accordingly, the drain regions arranged between the pair of adjacent second sidewalls (65b) are electrically isolated relative to each other.

On both sidewalls of the gate pattern (63′) (i.e., the first and the second sidewalls (65a, 65b)), a sidewall spacer (77) is arranged. The sidewall spacer may cover a portion of the sidewall of the silicide pattern (79). As illustrated in FIG. 2b and FIG. 2c, the sidewall spacers (77) on the pair of first sidewalls (65a) may be contacted and partly spaced from each other. The sidewall spacers (77) arranged respectively on the pair of adjacent second sidewalls (65b) may be spaced therebetween.

A barrier layer (82) may cover the semiconductor substrate conformally. A interlayer dielectric layer (84) may cover the semiconductor substrate (50). Preferably, the barrier layer (82) may include an insulating material having a etching rate lower than that of the interlayer dielectric layer (84). The interlayer dielectric layer (84) may include an oxide layer. The barrier layer (82) may be omitted.

The bitline contact (88) is connected to the drain region (75d) through the interlayer dielectric layer (84) and the barrier layer (82). The bitline contact (88) fills a contact hole (86) extending through the interlayer dielectric layer (84) and the barrier layer (82). The bitline contact (88) may include at least one selected from the group consisting of doped semiconductor, conductive metal nitride, metal silicide and metal. A bitline (not shown) may be arranged on the interlayer dielectric layer (84). The bitline is electrically connected to the drain region (75d) through the bitline contact (88). The bitline may extend in the first direction. As illustrated, the width of the drain region (75d) in the second direction may be wider than that of the source region (75s) in the second direction.

The source region (75s) extends beneath the concave region (70) and becomes included in the common source line. Therefore, a contact connected to the active region where the source region (75s) is formed may not be necessary. As a result, the integration density of the flash memory device may be enhanced.

As disclosed in FIG. 2d, it is preferable that a first top edge (95a) of the gate pattern (63′) adjacent to the drain region (75d) is lower than the center (100) of the upper surface of the gate pattern (63′), whereby the distance between the first top edge (95a) and the bitline contact (88) increases compared to the conventional art. Accordingly, electrical shortage between the control gate (80) and the bitline contact (88) may be prevented. Also, as illustrated, the upper corner of the control gate (80) may be round, whereby the distance between the control gate (80) and the bitline contact (88) may increase further. The width of the bitline contact (88) may be decreased as it goes on from its upper surface to its bottom. Accordingly, the distance between the first top edge (95a) and the bitline contact (88) may increase further.

A second top edge (95b) of the gate pattern (63′) adjacent to the source region (75s) may be lower than the center of the upper surface of the gate pattern (63′). The first sidewall (65a) and the second sidewall (65b) may be perpendicular to the upper surface of the active region (53) and be symmetric with each other with reference to an imaginary vertical line (110) running through the center (100). In addition, the first and the second top edges (95a, 95b) may be symmetric with each other with reference to the imaginary vertical line (100).

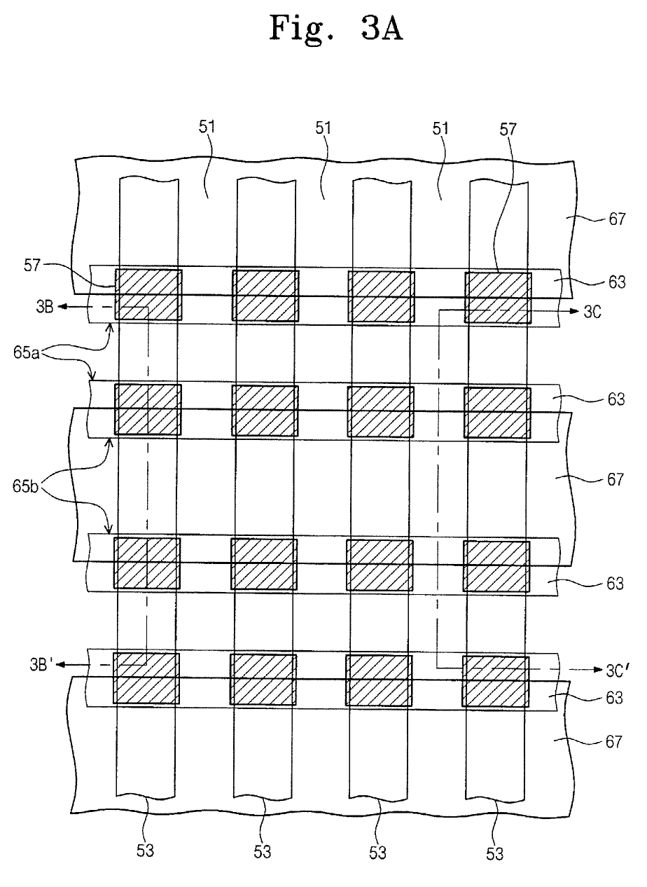

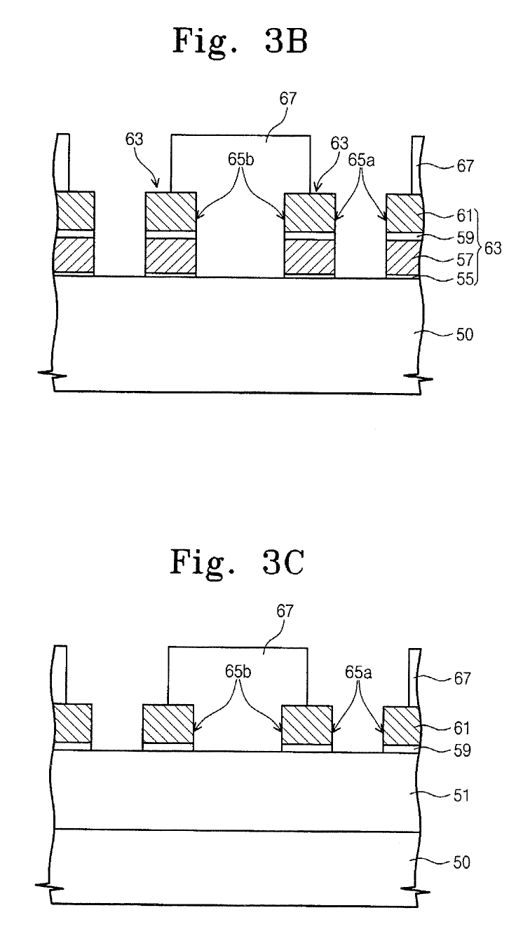

A manufacturing method for the nonvolatile memory device in accordance with an embodiment of the present invention will now be described with reference to FIGS. 3a-7a, 3b-7b, 3c-7c and 2a-2d. FIG. 3a through FIG. 7a represents plan views for describing a manufacturing method for the nonvolatile memory device according to an embodiment of the present invention.

Referring to FIG. 3a, FIG. 3b, FIG. 3c, a plurality of active regions (53) are defined by forming a device isolation layer (51) on a semiconductor substrate (50). The device isolation layer (51) may be formed as a shallow trench isolation (STI) layer. For example, a method of forming the device isolation layer (51) may include forming a trench defining the active regions (53) on the semiconductor substrate (50) and then forming an insulating material filling the trench. Gate patterns (63) are formed to cross the active regions (53) and the device isolating layer (51) in parallel. The gate pattern (63) includes a tunnel insulating layer (55), a charge storage layer (57), a blocking insulating layer (59) and a conductive line pattern (61). The conductive line pattern (61) crosses the upper region of the active regions (53) and the device isolation layer (51). The conductive line pattern (61) is included in a control gate. The conductive line pattern (61) is formed from a conductive material. The conductive line pattern (61) may include a semiconductor material including silicon. Alternatively, the conductive line pattern (61) may include a conductive material having sufficiently low resistivity, such as a conductive metal nitride or metal.

The gate pattern (63) includes a first sidewall (65a) and a second opposing sidewall (65b). The first sidewall (65a) is adjacent one side of the gate pattern (63), and the second sidewall (65b) is adjacent another side of the gate pattern (63). A pair of adjacent gate patterns (63) are symmetric with each other. Accordingly, the pair of adjacent first sidewalls (65a) and the pair of adjacent second sidewalls oppose each other.

A preliminary mask pattern (67) covering the active region (53) adjacent to the other side of the gate pattern (63) and the device isolating layer (51) is formed. The preliminary mask pattern (67) covers the pair of adjacent second sidewalls (65b). Also, in order to secure an alignment margin of the preliminary mask pattern (67), it covers a portion of the upper surfaces of the gate patterns (63) adjacent thereto. The preliminary mask pattern (67) extends in parallel with the gate pattern (63). The active regions (53) and the device isolation layer (51) adjacent to the one side of the gate pattern (63) are exposed. In other words, the active regions (53) and the device isolation layer (51) between the pair of adjacent first sidewalls (65a) are exposed. Also, the pair of adjacent first sidewalls (65a) is exposed.

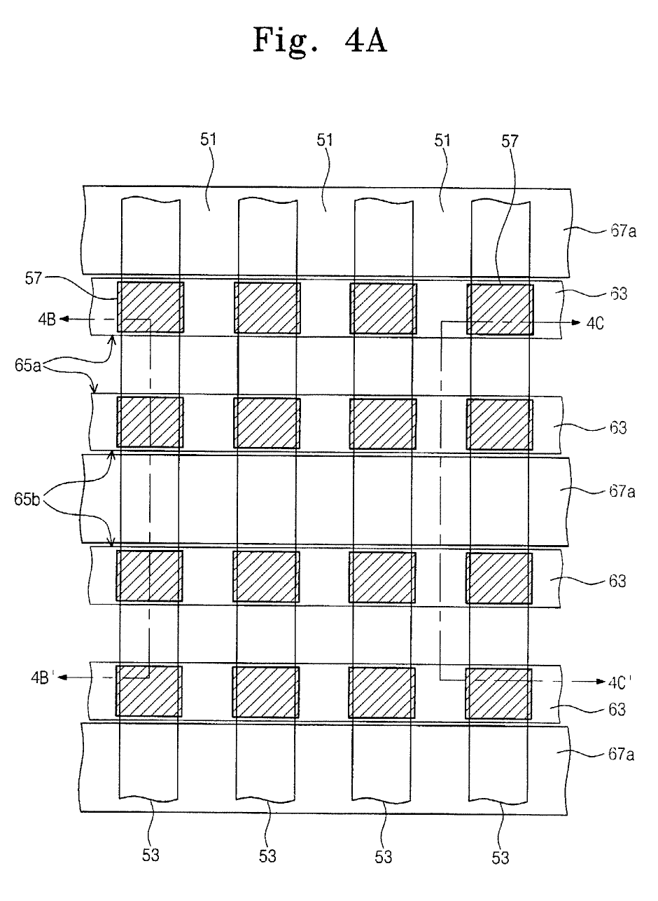

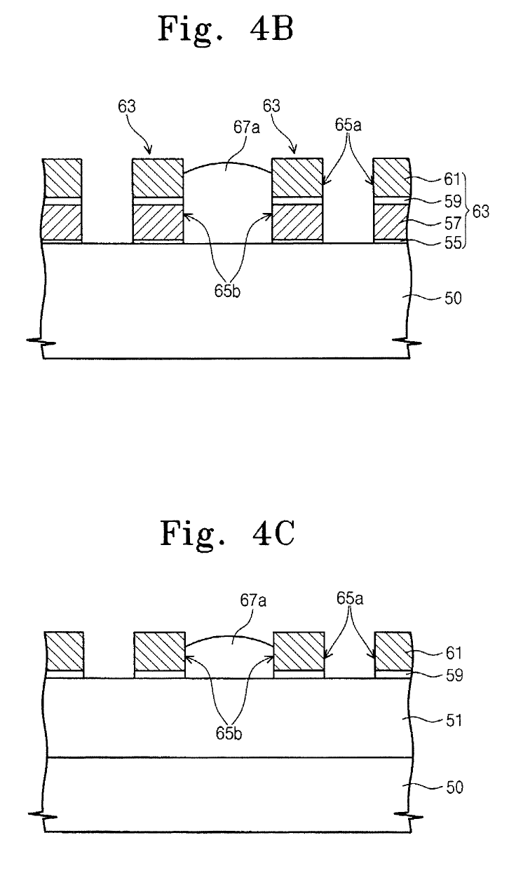

Referring to FIG. 4a, FIG. 4b, and FIG. 4c, a portion of the preliminary mask pattern (67) is removed (e.g., etched-back) until the entire upper surface of the gate pattern (63) is exposed, whereby a mask pattern (67a) is formed. The exposed upper surface of the gate pattern (63) is an upper surface of the conductive line pattern (61). The preliminary mask pattern (67) may comprise a photoresist. Then, a portion of the preliminary mask pattern (67) may be removed by an oxygen plasma ashing process. The oxygen plasma ashing process etches a portion of the preliminary mask pattern (67) using an oxygen gas in a plasma state. During the oxygen plasma ashing process, a back bias accelerating the oxygen gas in a plasma state toward the semiconductor substrate (50) may be provided. Alternatively, the back bias may not be provided, whereby the preliminary mask pattern may be etched isotropically by the oxygen plasma ashing process. As a result, the edge of the upper surface of the mask pattern (67a) may be formed lower than the center of the upper surface of the mask pattern (67a).

Alternatively, the portion of the preliminary mask pattern (67) may be removed by a wet etching process. For example, when the preliminary mask pattern (67) is a photoresist, the wet etching process may be performed using an etching solution including hydrosulfuric acid. The wet chemical etching corresponds to isotropic etching.

It is preferable that the edge of the mask pattern (67a) adjacent to the gate pattern (63) be lower than the upper surface of the gate pattern (63). Accordingly, the upper portion of the second sidewall (65b) of the gate pattern (63) is exposed. Finally, the first and second sidewalls (65a, 65b) of the gate pattern (63) may be exposed. The entire upper surface of the mask pattern (67a) may be formed lower than the upper surface of the gate pattern (63). In accordance with other embodiment of the present invention, the mask pattern (67a) may cover the entire second sidewall (65b) of the gate pattern (63).

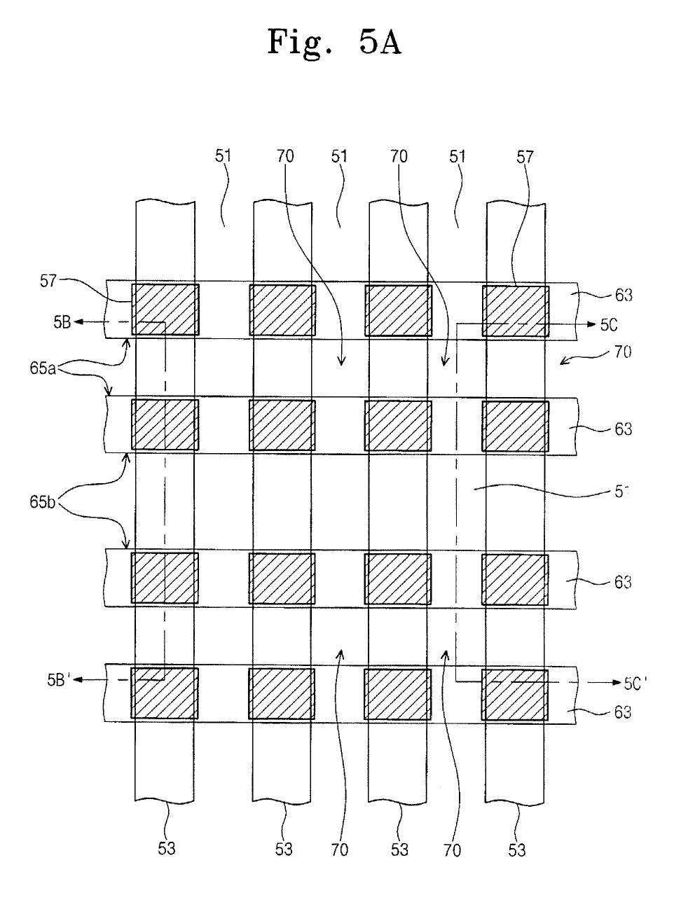

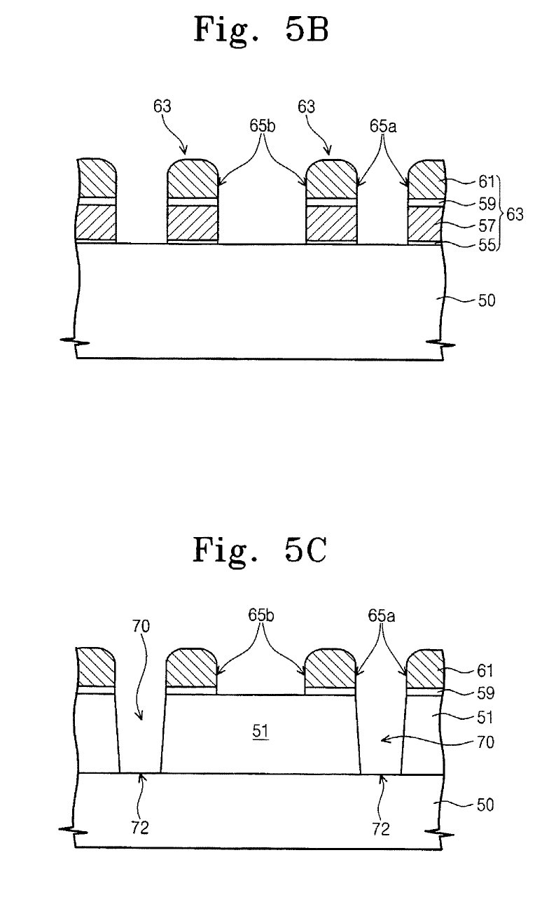

Referring to FIG. 5a, FIG. 5b, and FIG. 5c, exposed device isolation layer (51) is etched away using the mask pattern (67a) as a mask, whereby concave regions (70) (e.g., openings) are formed between the pair of adjacent first sidewalls (65a). The concave regions (70) and the active regions (53) are alternately arranged between the adjacent first sidewalls (65a) in the direction along which the gate pattern (63) extends. Beneath the bottom surface (72) of the concave region (70) is a semiconductor substrate (50). For convenience's sake, the process for etching the exposed device isolation layer (51) is defined as a device isolation layer etching process.

Exposed device isolation layer (51) may be completely removed by the device isolation layer etching process, whereby the concave region (70) may expose the semiconductor substrate (50). Alternatively, in order to protect the semiconductor substrate (50) beneath the exposed device isolation layer (51), a portion of the exposed device isolation layer (51) (i.e., a residue) may remain after the device isolation layer etching process. In this case, the bottom surface (72) of the concave region (70) may include residues of the device isolation layer (51). It is preferable that the residue of the device isolation layer (51) be thin enough to be used as a buffer layer for subsequent ion implantation. The device isolation etching process may be performed by an anisotropic etching process.

During the device isolation layer etching process, the upper portion of the gate pattern (63) (i.e., the conductive line pattern (61)) also is etched away. The first etching rate of the device isolation layer (51) is faster than the second etching rate of the conductive line pattern (61). For example, the first etching rate may be 10 times through 30 times greater than the second etching rate. Alternatively, the first etching rate may be several times through several hundreds times greater than the second etching rate.

As stated in detail above, the edge of the mask pattern (67a) adjacent to the gate pattern (63) is formed lower than the upper surface of the gate pattern and the upper portion of the second sidewall (65b) of the gate pattern (63) is exposed. During the device isolation layer etching process, the upper corner of the conductive line pattern (61) adjacent to the mask pattern (67a) is etched more than the center of the upper surface of the conductive line pattern (61). Because the first sidewall (65a) of the gate pattern (63) also is exposed, both upper corners of the gate pattern (63) are etched more than the center of the upper surface of the conductive line pattern (61). As a result, after the device isolation layer etching process, both upper edges of the conductive line pattern (61) becomes formed lower than the center of the upper surface of the conductive line pattern (61). After the device isolation layer etching process, both upper edges of the conductive line pattern (61) may be formed in round shape.

When the edge of the mask pattern (67a) is lower than the upper surface of the conductive line pattern (61), after the device isolation layer etching process, both sidewalls of the gate pattern (63) may be formed symmetrically with reference to the imaginary vertical line (110) as shown in FIG. 2d.

Alternatively, the mask pattern (67a) may cover the entire second sidewall (65a) of the gate pattern (63). In this case, it is preferable that the etching rate of the mask pattern (67a) is faster than that of the conductive line pattern (61) during the device isolation layer etching process. Thus, the mask pattern (67a) is etched before the conductive line pattern (61), and the upper portion of the second sidewall (65b) becomes exposed. As a result, during the device isolation layer etching process, the upper edge of the conductive line pattern (61) may be etched more than the center of the upper surface of the conductive line pattern (61). Namely, the upper edge of the conductive line pattern (61) adjacent to the mask pattern (67a) may be formed lower than the center of the upper surface of the conductive line pattern (61).

After forming the concave regions (70), the mask pattern (67a) is removed.

Referring to FIG. 6a, FIG. 6b, and FIG. 6c, the active regions (51) adjacent to the one side of the gate pattern (63) and source regions (75s) beneath the concave regions (70) are formed on the semiconductor substrate (50). Namely, the active regions (53) between the pair of adjacent first sidewalls (65a) and the source regions (75s) beneath the concave regions (70) are formed. Drain regions (75d) are formed on the active regions (51) adjacent to the other side of the gate pattern (63), respectively. Namely, the drain regions (75d) are formed on the active regions (51) between the pair of adjacent second sidewalls (65b). The drain and source regions (75d, 75s) may be formed by implanting dopants. The drain region (75d) and the source region (75s) may be formed simultaneously. Alternatively, the drain region (75d) and the source region (75s) may be formed sequentially.

Sidewall spacers (77) are formed on both sidewalls of the gate pattern (63). The sidewall spacers formed on the drain region (75d) may be spaced therebetween. The sidewall spacers (77) formed on the source region (75s) may be connected or partly spaced as to each other. According to one embodiment of the present invention, the sidewall spacers (77) formed on the source region (75s) may be completely spaced therebetween.

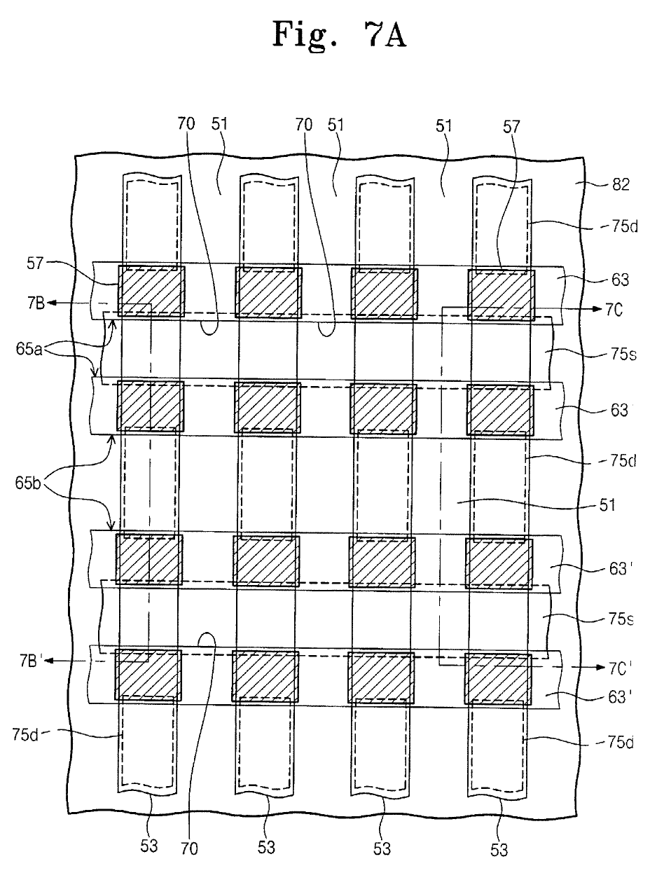

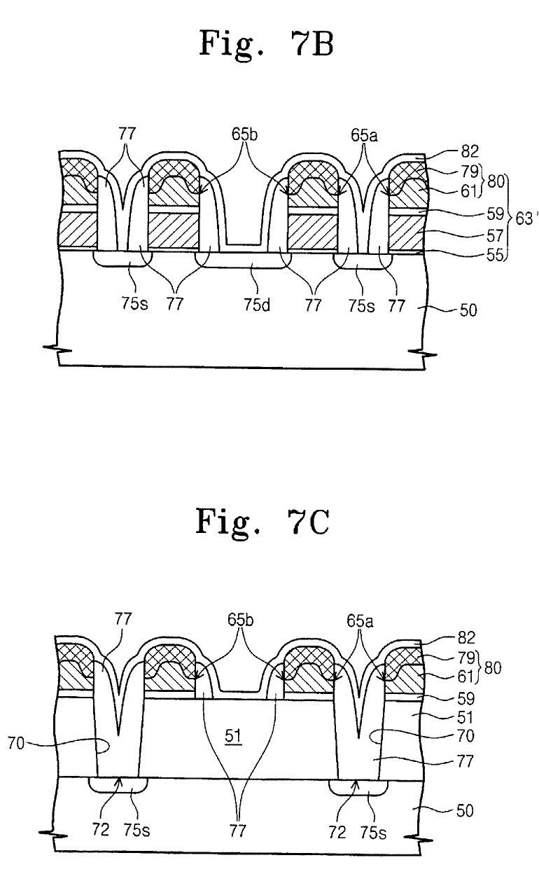

Referring to FIG. 7a, FIG. 7b, FIG. 7c, a silicide pattern (79) may be formed on the conductive line pattern (61). As stated above, the conductive line pattern (61) may include a semiconductor material including silicon. It is preferable that the silicide pattern (79) be formed by a self-aligned silicidation process. The self-aligned silicidation process is described specifically below. A metal layer is formed on the semiconductor substrate (50). Through a silicidation process, the metal layer reacts with the conductive line pattern (61) to form the silicide pattern (79) on the semiconductor substrate (50). Thereafter, unreacted portions of the metal layer are removed. The process of forming the metal layer and the silicidation process may be performed sequentially, or in-situ. The conductive line pattern (61) and the silicide pattern (79) constitute the control gate (80).

After the silicidation process, the upper surface of the silicide pattern (79) may be substantially identical to the morphology of the upper surface of the conductive line pattern (61) after the device isolation layer etching process. Accordingly, the upper edge of the silicide pattern (79) adjacent to the drain region (75d) is formed lower than the center of the upper surface of the gate pattern (63′). The silicide pattern (79) may be formed higher than the sidewall spacer (77).

The silicide pattern (79) may be formed from various metal silicides. Preferably, the silicide pattern (79) may be formed from cobalt silicide or nickel silicide. Even though not illustrated, during the silicidation process, silicides may be formed on the exposed surface of the drain region (75d) and/or the source region (75s).

According to one embodiment of the present invention, the conductive line pattern may include a conductive material having sufficiently low resistivity. In this case, the silicide pattern forming process may be omitted, and the control gate may comprise only the conductive line pattern (61).

Then, a barrier layer (82) may be formed to cover the semiconductor substrate (50). The barrier layer (82) may be formed conformally. An interlayer dielectric layer (84) is formed on the barrier layer (72). The barrier layer (82) may include an insulating layer having low etching rate relative to the interlayer dielectric layer (84). For example, when the interlayer dielectric layer (84) is formed from an oxide layer, the barrier layer may be formed from a nitride layer.

Then, the interlayer dielectric layer (84) and the barrier layer (82) are patterned continuously and a contact hole (86) exposing the drain region (75) is formed, as shown in FIG. 2a and FIG. 2b. A bitline contact (88) filling the contact hole (86) as shown in FIG. 2a and FIG. 2b, is then formed. Therefore, a nonvolatile memory device as illustrated in FIG. 2a, FIG. 2b and FIG. 2c may be implemented.

In accordance with a manufacturing method for the nonvolatile memory device as stated above, after exposing the entire upper surface of the gate pattern (63) by removing a portion of the preliminary mask pattern (67), the device isolation layer etching process is performed. Accordingly, the upper edge of the gate pattern (63) adjacent to the drain region (75d) is formed lower than the center of the upper surface of the gate pattern (63). As a result, the distance between the control gate (80) and the bitline contact (88) may increase, thereby preventing an electrical shortage between the control gate (80) and the bitline contact (88).

Thus, referring again to FIGS. 4a-4c, methods of forming non-volatile memory devices according to embodiments of the present invention include forming a device isolation layer 51 and a gate pattern 63 of a non-volatile memory cell transistor, on a semiconductor substrate 50. This gate pattern 63 includes a floating gate electrode 57 and a control gate line 61 that extends on the floating gate electrode 57 and on the device isolation layer 51. At least a first portion of a first sidewall 65b of the gate pattern 63 is then covered with a first mask 67a that exposes upper corners of the control gate line 61. Then, as illustrated by FIGS. 5a-5c, the device isolation layer 51 is then selectively etched at a first rate to define an at least partial opening 70 therein. During this etching step, the upper corners of the control gate line 61 are also etched back at a second rate less than the first rate. The first mask 67a is used as an etching mask during these etching steps. Referring now to FIGS. 6a-6c, source region dopants are then implanted through the at least partial opening in the device isolation layer and into the semiconductor substrate to define a source region 75s therein. Sidewall insulating spacers 77 are also formed on opposing sidewalls of the gate pattern 63. Then, as illustrated by FIGS. 2a-2c, an interlayer dielectric layer 84 is formed on the gate pattern 63′. A step is performed to selectively etch through the interlayer dielectric layer 84 and define a contact hole therein 86 that exposes the semiconductor substrate 50. The contact hole is then filled with a bit line contact 88.

Alternatively, sidewall insulating spacers 77 may be formed on opposing sidewalls of the gate pattern 63 and then an electrically insulating barrier layer 82, formed of a first electrically insulating material, is formed on the sidewall insulating spacers 77. An interlayer dielectric layer 84, formed of a second electrically insulating material that is different from the first electrically insulating material, is then formed on the gate pattern 63′. The interlayer dielectric layer 84 and the electrically insulating barrier layer 82 are then etched in sequence to define a contact hole 86 therein that exposes the semiconductor substrate 50. The contact hole is filled with a bit line contact 88.

In the drawings and specification, there have been disclosed typical preferred embodiments of the invention and, although specific terms are employed, they are used in a generic and descriptive sense only and not for purposes of limitation, the scope of the invention being set forth in the following claims.

1. A method of forming a non-volatile memory device, comprising:
forming a device isolation layer on a semiconductor substrate;
forming a gate pattern of a non-volatile memory cell transistor on the semiconductor substrate, said gate pattern comprising a floating gate electrode and a control gate line that extends on the floating gate electrode and on the device isolation layer;
covering at least a first portion of a first sidewall of the gate pattern with a first mask that exposes upper corners of the control gate line; and
selectively etching the device isolation layer at a first rate to define an at least partial opening therein while simultaneously etching back the upper corners of the control gate line at a second rate less than the first rate, using the first mask as an etching mask.

2. The method of claim 1, wherein said covering comprises:
depositing a mask layer on the gate pattern;
photolithographically patterning the mask layer to define a preliminary mask pattern that exposes a second sidewall of the gate pattern and exposes an upper surface of the device isolation layer; and then
etching back the preliminary mask pattern for a sufficient duration to define the first mask, which exposes an upper surface of the gate pattern and exposes a second portion of the first sidewall.

3. The method of claim 2, wherein etching back the preliminary mask pattern comprises exposing the preliminary mask pattern to an oxygen plasma.

4. The method of claim 2, wherein etching back the preliminary mask pattern comprises exposing the preliminary mask pattern to a wet etchant comprising sulfuric acid.

5. The method of claim 2, wherein the preliminary mask pattern comprises a photoresist material.

6. The method of claim 1, further comprising implanting source region dopants through the at least partial opening in the device isolation layer and into the semiconductor substrate to define a source region therein.

7. The method of claim 6, further comprising:
forming sidewall insulating spacers on opposing sidewalls of the gate pattern;
forming an interlayer dielectric layer on the gate pattern;
selectively etching through the interlayer dielectric layer to define a contact hole therein that exposes the semiconductor substrate; and
filling the contact hole with a bit line contact.

8. The method of claim 6, further comprising:
forming sidewall insulating spacers on opposing sidewalls of the gate pattern;
forming an electrically insulating barrier layer comprising a first electrically insulating material on the sidewall insulating spacers;
forming an interlayer dielectric layer comprising a second electrically insulating material, which is different from the first electrically insulating material, on the gate pattern;
selectively etching through the interlayer dielectric layer and the electrically insulating barrier layer in sequence to define a contact hole therein that exposes the semiconductor substrate; and
filling the contact hole with a bit line contact.

9. A method of forming a nonvolatile memory device, comprising the steps of:
forming a device isolation layer to define an active region on a semiconductor substrate;
forming a gate pattern crossing the active region and having a first and a second sidewall which oppose each other;
forming a concave region by etching the device isolation layer arranged adjacent to the first sidewall of the gate pattern; and
etching the gate pattern to form the upper edge of the gate pattern adjacent to the second sidewall lower than the center of the upper surface of the gate pattern.

10. The method of claim 9, wherein the step of etching the gate pattern and the step of forming a concave region are performed simultaneously.

11. The method of claim 10, wherein the etching rate of the device isolation layer is faster than that of the gate pattern.

12. The method of claim 10, wherein the step of etching the gate pattern and the step of forming a concave region comprise
forming a mask pattern covering the active region adjacent to the second sidewall of the gate pattern and the device isolation layer, the mask pattern exposing the entire upper surface of the gate pattern and the device isolation layer adjacent to the first sidewall of the gate pattern; and
etching the device isolation layer and the gate pattern with the mask pattern as an etching mask.

13. The method of claim 12, wherein the step of forming a mask pattern comprises
forming a preliminary mask pattern covering the active region adjacent to the second sidewall of the gate pattern and a portion of the upper surface of the gate pattern; and
forming a mask pattern to expose the upper surface of the gate pattern by removing a portion of the preliminary mask pattern.

14. The method of claim 13, wherein the preliminary mask pattern is formed from a photoresist and wherein a portion of the preliminary mask pattern is removed by oxygen plasma ashing process or wet etching process.

15. The method of claim 12, wherein the edge of the mask pattern adjacent to the gate pattern is formed lower than the upper surface of the gate pattern.

16. The method of claim 12, wherein the mask pattern covers the entire first sidewall of the gate pattern and wherein the etching rate of the mask pattern is faster than that of the gate pattern.

17. The method of claim 9, wherein the upper edge of the gate pattern adjacent to the second sidewall is formed in round shape.

18. The method of claim 9, farther comprising the steps of
forming a source region on the active region adjacent to the first sidewall of the gate pattern and beneath the concave region on the semiconductor substrate; and
forming a drain region on the active region adjacent to the second sidewall of the gate pattern.

19. The method of claim 9, wherein the gate pattern comprises
a conductive line pattern crossing the active region;
a charge storage layer interposed between the conductive line pattern and the active region;
a tunnel insulating layer interposed between the charge storage layer and the active region; and
a blocking insulating layer interposed between the charge storage layer and the conductive line pattern and wherein the conductive line pattern is included in a control gate and wherein the upper surface of the gate pattern is the upper surface of the conductive line pattern.

20. The method of claim 19, further comprising the steps of
forming sidewall spacers on both sidewalls of the gate pattern; and
forming a silicide pattern on the conductive line pattern, and wherein the conductive line pattern comprises a semiconductor including silicon and wherein the silicide pattern is formed by self-aligned silicidation process, and wherein the control gate comprises the conductive line pattern and the silicide pattern.

21. The method of claim 20, wherein the silicide pattern is at least one from cobalt silicide and nickel silicide.

22. The method of claim 9, further comprising the steps of
forming an interdielectric layer covering the semiconductor substrate;
forming a bitline contact to be connected to the active region adjacent to the second sidewall of the gate pattern through the interdielectric layer.

23. The method of claim 22, further comprising the step of
forming a barrier layer having an etching rate slower than that of the interdielectric layer on the semiconductor substrate before forming the interdielectric layer, and wherein the bitline contact is connected to the active region adjacent to the second sidewall of the gate pattern through the interdielectric layer and the barrier layer.

24-32. (canceled)
